(19) United States
(12) Patent Application Publication
(10) Pub. No.: US 2026/0164629 A1
(43) Pub. Date: Jun. 11, 2026

(54) MAINTENANCE TOOL AND METHOD OF ACCESSING POWER CABLES IN A POWER DISTRIBUTION ASSEMBLY

(71) Applicant: VERTIV CORPORATION, Westerville, OH (US)

(72) Inventors: Vinayak PATIL, Pune (IN); Rupesh PANDITKAR, Pune (IN); Omkar Suresh VICHARE, Pune (IN)

(73) Assignee: VERTIV CORPORATION, Westerville, OH (US)

(21) Appl. No.: 19/408,973

(22) Filed: Dec. 4, 2025

(30) Foreign Application Priority Data
Dec. 6, 2024 (IN) 202421096558

(51) Int. Cl. H05K 13/00; H02B 1/20; H02G 1/00

(52) U.S. Cl. CPC H05K 13/0007; H02B 1/202; H02G 1/00

(57) ABSTRACT

A maintenance tool and a method of accessing power cables in a power distribution assembly is disclosed. A handle configured for single-handed ergonomic operation and including an electrically insulated exterior surface. A bracket mechanically coupled to the handle. The bracket having a specialized cutout configured to support and stabilize one or more power cables while reducing mechanical stress on a circuit breaker terminal of a circuit breaker of the power distribution assembly. A locking mechanism integrated within the maintenance tool and operable through the handle to engage or disengage the one or more power cables from the circuit breaker terminal. The bracket positions the one or more power cables in a stable orientation, and the locking mechanism, in coordination with the bracket, operates to selectively secure or release the one or more power cables from the circuit breaker terminal.

### CROSS-REFERENCE TO RELATED APPLICATION

This application claims the priority under 35 USC § 119 to Indian Provisional Patent Application No. 202421096558 entitled “A Tool and a Method for Universal Cable Access and Maintenance in Power Systems” filed Dec. 6, 2024, the disclosure of which is hereby expressly incorporated by reference in its entirety.

### TECHNICAL FIELD

The present invention generally relates to the field of electrical maintenance tools, and more particularly to a maintenance tool and method of accessing power cables in a power distribution assembly.

### BACKGROUND

In power distribution assemblies, accessing and managing power cables can be a complex and time-consuming task, particularly in confined or hard-to-reach areas. Traditional methods often require the use of multiple tools to install, remove, or adjust cables, leading to inefficiency and increased risk of damage to components. Additionally, handling heavy cables and working near circuit breakers can place mechanical stress on terminals, complicating maintenance and repair processes, and requiring frequent disassembly of components.

### SUMMARY OF THE INVENTION

This summary is provided to introduce aspects related to a maintenance tool and a method of accessing power cables in power distribution assembly. The maintenance tool provides an efficient and ergonomic solution for installing, removing, and adjusting power cables, particularly in confined spaces. The maintenance tool reduces the need for multiple devices, enhances safety by minimizing mechanical stress on circuit breaker terminals, and allows for single-handed operation, thereby improving the overall maintenance process and reducing downtime in power distribution systems.

In an aspect, a maintenance tool for accessing power cables in a power distribution assembly is disclosed. The maintenance tool may include a handle configured for single-handed ergonomic operation and including an electrically insulated exterior surface. The maintenance tool may further include a bracket mechanically coupled to the handle, the bracket having a specialized cutout configured to support and stabilize one or more power cables while reducing mechanical stress on a circuit breaker terminal of a circuit breaker of the power distribution assembly. The maintenance tool may further include a locking mechanism integrated within the maintenance tool and operable through the handle to engage or disengage the one or more power cables from the circuit breaker terminal. The handle, the bracket, and the locking mechanism cooperatively enable installation, removal, and adjustment of the one or more power cables in the circuit breaker terminal without requiring removal of the circuit breaker. The bracket positions the one or more power cables in a stable orientation, and the locking mechanism, in coordination with the bracket, operates to selectively secure or release the one or more power cables from the circuit breaker terminal, thereby ensuring secure engagement or disengagement of the one or more power cables from the circuit breaker terminal.

In another aspect, embodiments include a method of accessing power cables in a power distribution assembly. The method may include providing a maintenance tool for accessing one or more power cables. The maintenance tool may include a handle configured for single-handed ergonomic operation and including an electrically insulated exterior surface. The maintenance tool may further include a bracket mechanically coupled to the handle, the bracket having a specialized cutout configured to support and stabilize the one or more power cables while reducing mechanical stress on a circuit breaker terminal of a circuit breaker in the power distribution assembly. The maintenance tool may further include a locking mechanism integrated within the maintenance tool and operable through the handle to engage or disengage the one or more power cables from the circuit breaker terminal. The method may further include positioning the handle, the bracket, and the locking mechanism relative to the circuit breaker such that the handle and the bracket cooperatively enable installation, removal, and adjustment of the one or more power cables in the circuit breaker terminal without requiring removal of the circuit breaker. The bracket positions the one or more power cables in a stable orientation, and the locking mechanism, in coordination with the bracket, and operates to selectively secure or release the one or more power cables from the circuit breaker terminal, thereby ensuring secure engagement or disengagement of the one or more power cables from the circuit breaker terminal.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying figures of the drawing, which are included to provide a further understanding of general aspects of the system/method, are incorporated in and constitute a part of this specification. These illustrative aspects of the system/method, and together with the detailed description, explain the principles of the system. No attempt is made to show structural details in more detail than is necessary for a fundamental understanding of the system and various ways in which it is practiced. The following figures of the drawing include:

FIG. 1 illustrates a conventional setup where multiple power cables are routed through a power distribution assembly.

FIG. 2 illustrates a perspective view of a maintenance tool.

FIG. 3 depicts the maintenance tool accessing the power cables in a power distribution assembly.

FIG. 4 is a flowchart of a method of accessing power cables in the power distribution assembly using the maintenance tool.

In the appended figures, similar components and/or features may have the same numerical reference label. Further, various components of the same type may be distinguished by following the reference label with a letter. If only the first numerical reference label is used in the specification, the description is applicable to any one of the similar components and/or features having the same first numerical reference label irrespective of the suffix.

### LIST OF REFERENCE NUMERALS

100—Power Distribution Assembly
102—Power Cables
200—Maintenance Tool
202—Handle
204—Bracket
206—Locking Mechanism
302—Circuit Breaker Terminal

### DETAILED DESCRIPTION OF THE INVENTION

Illustrative embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the spirit and scope of the disclosed embodiments. It is intended that the following detailed description be considered as exemplary only, with the true scope and spirit being indicated by the following claims.

In power distribution assemblies, accessing and managing power cables can be a challenging and time-consuming task, especially in confined spaces. Traditional methods often require multiple tools for cable installation, removal, and adjustment, leading to inefficiency, increased risk of damage to the components, and operator fatigue. Furthermore, the mechanical stress on the circuit breaker terminals from heavy cables can result in system failures or damage during maintenance operations. These challenges make servicing power distribution assemblies both difficult and inefficient, increasing downtime and the likelihood of operational issues.

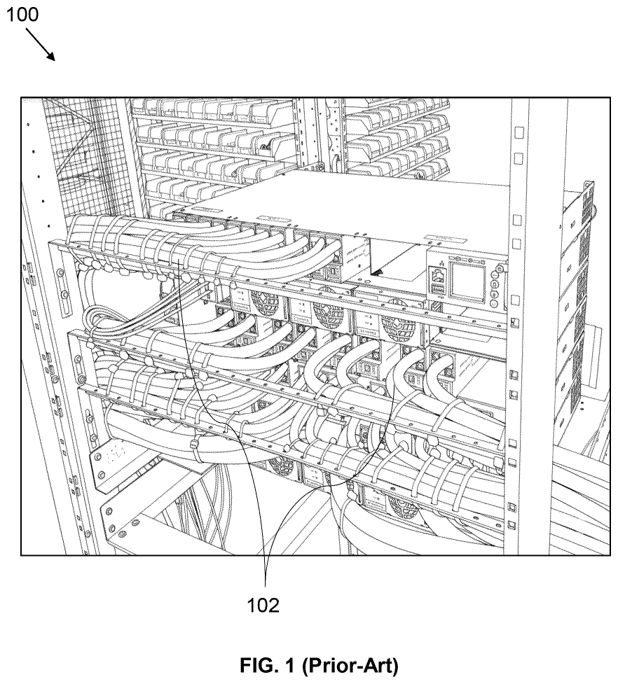

The present disclosure addresses these challenges by providing a maintenance tool designed for accessing and managing power cables in power distribution assemblies. The tool features an ergonomically designed handle for single-handed operation, a bracket that stabilizes and supports the cables, and a locking mechanism for securely engaging or disengaging the power cables from the circuit breaker terminal. These elements work together to enable efficient cable handling, reducing the need for multiple tools, minimizing strain on the circuit breaker terminals, and allowing for quick, safe, and easy maintenance without the need to remove the circuit breaker. The adjustability of the bracket and the quick-release feature of the locking mechanism provide added flexibility and ease of use, ensuring the tool can be applied in various power distribution setups, improving overall efficiency and safety during maintenance tasks. The present disclosure, along with these and other aspects, will now be described in detail with reference to FIG. 1 through FIG. 4.

FIG. 1 illustrates a conventional setup where multiple power cables 102 are routed through a power distribution assembly 100, connecting various components such as circuit breakers, terminals, and other electrical infrastructure. In conventional power distribution assemblies, these power cables 102 are often densely packed and routed in hard-to-reach areas, making maintenance and adjustments difficult and time-consuming.

The challenge with this traditional arrangement is that the power cables 102 are often tightly clustered, which complicates access to specific components such as the circuit breaker terminals. In many cases, service personnel are required to use multiple tools and may have to disassemble parts of the power distribution assembly 100 or lift the circuit breakers to properly manage the power cables 102. This process not only increases the complexity and time required for maintenance but also raises the risk of damaging the circuit breaker terminals or other components due to mechanical stress, improper handling, or accidental disconnections.

Additionally, the confined spaces in which the power cables 102 are routed increase the difficulty of performing maintenance safety and efficiently. Without a proper tool for quick and effective cable handling, service personnel may struggle to complete necessary tasks, leading to longer downtime and potential operational disruptions.

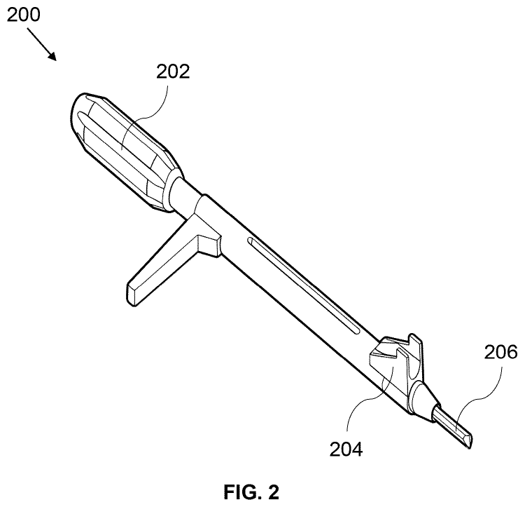

FIG. 2 illustrates a perspective view of a maintenance tool 200. The maintenance tool 200 may include a handle 202 configured for single-handed ergonomic operation and including an electrically insulated exterior surface.

The maintenance tool 200 may further include a bracket 204 mechanically coupled to the handle 202. The bracket 204 having a specialized cutout configured to support and stabilize the power cables 102 while reducing mechanical stress on a circuit breaker terminal of a circuit breaker of the power distribution assembly 100. The specialized cutout of the bracket 204 may be shaped to receive the power cables 102 of multiple diameters and maintain axial alignment during tightening or loosening operations. The bracket 204 may be adjustably mounted relative to the handle to accommodate circuit breakers of varying dimensions and orientations.

The maintenance tool 200 may further include a locking mechanism 206 integrated within the maintenance tool 200 and operable through the handle 202 to engage or disengage the power cables 102 from the circuit breaker terminal. The locking mechanism 206 may include a pressing screw or cam element configured to selectively secure or release the power cables 102 using a single-handed motion applied to the handle 202. The locking mechanism 206 may further include a quick-release element configured to disengage the power cables 102 from the circuit breaker terminal without displacing the bracket 204 or the handle 202.

The handle 202, the bracket 204, and the locking mechanism 206 cooperatively enable installation, removal, and adjustment of the power cables 102 in the circuit breaker terminal without requiring removal of the circuit breaker. The bracket 204 positions the power cables 102 in a stable orientation, and the locking mechanism 206, in coordination with the bracket 204, operates to selectively secure or release the power cables 102 from the circuit breaker terminal, thereby ensuring secure engagement or disengagement of the power cables 102 from the circuit breaker terminal.

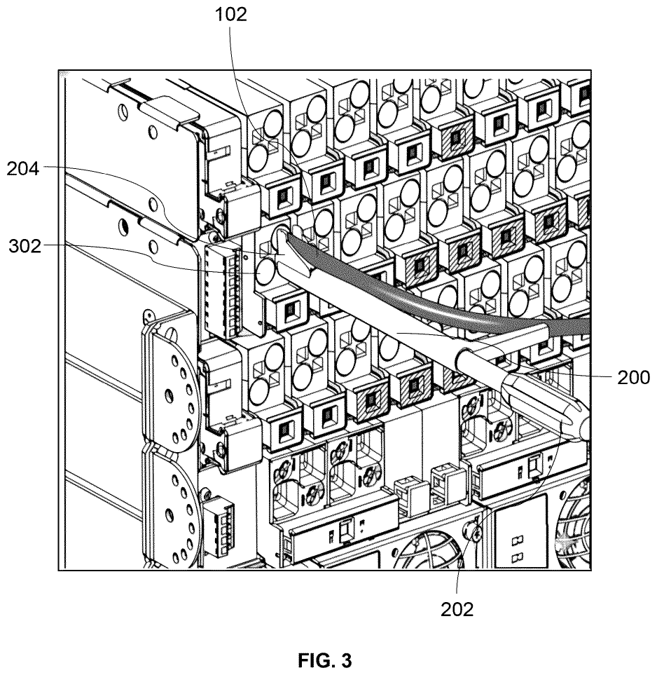

FIG. 3 depicts the maintenance tool 200 accessing the power cables 102 in the power distribution assembly 100. In this figure, the maintenance tool 200 is shown in operational use, with the handle 202, the bracket 204, and the locking mechanism 206 interacting to manage the power cables. The bracket 204, mechanically coupled to the handle 202, includes a specialized cutout that supports and stabilizes the power cables 102 while reducing mechanical stress on a circuit breaker terminal in the power distribution assembly 100. The cutout of the bracket 204 is designed to receive the power cables 102 of varying diameters and maintain their axial alignment during tightening or loosening operations, ensuring precise cable management in tight spaces.

As shown in FIG. 3, the locking mechanism 206 integrated within the tool enables secure engagement or disengagement of the power cables 102 from the circuit breaker terminal 302. The locking mechanism 206 includes a pressing screw or cam element that allows for single-handed operation of the tool. The quick-release feature further enhances the tool's efficiency by enabling the power cables 102 to be quickly disengaged from the circuit breaker terminal 302 without displacing the bracket 204 or the handle 202. The handle 202, the bracket 204, and the locking mechanism 206 together enable the installation, removal, and adjustment of power cables 102 without the need for circuit breaker removal, facilitating faster and safer maintenance in power distribution systems.

In a power distribution assembly 100 of a data center, service personnel need to perform routine maintenance on the power cables 102 that connect to various circuit breaker terminals 302. The circuit breaker assembly is located in a confined rack space, with the cables 102 tightly routed and difficult to access. To facilitate the maintenance process, the technician uses the maintenance tool 200, which includes the handle 202, the bracket 204, and the locking mechanism 206. The technician begins by positioning the handle 202 of the maintenance tool 200 over the power distribution assembly 100, ensuring the bracket 204 is aligned with the power cables 102.

The bracket 204, which has a specialized cutout, supports and stabilizes the power cables 102 as the technician adjusts the tool's position. The cutout is designed to accommodate cables of varying diameters, ensuring that regardless of cable size, the cables are aligned and properly supported, thereby reducing any risk of damage to the circuit breaker terminal 302. Next, the technician uses the locking mechanism 206, which is integrated into the handle 202. By applying a single-handed motion, the technician engages the locking mechanism 206, securing the power cables 102 in place. The pressing screw or cam element of the mechanism ensures that the cables are held firmly against the circuit breaker terminal 302, preventing accidental disconnections.

The technician then adjusts the power cables 102 using the maintenance tool 200 to either install new cables, remove old ones, or reposition the cables for optimal performance. During this operation, the quick-release element of the locking mechanism 206 comes into play. When the technician needs to disengage the power cables 102, they simply trigger the quick-release function, which allows for the rapid and secure detachment of the cables from the circuit breaker terminal 302, all without moving the bracket 204 or handle 202. Once the maintenance task is completed, the technician repositions the bracket 204 and the locking mechanism 206 as needed and finishes securing the power cables 102 in place. The entire operation is completed efficiently, without the need to remove the circuit breaker from the assembly, reducing downtime and improving the speed and safety of the maintenance procedure.

Once the maintenance task is completed, the technician repositions the bracket 204 and locking mechanism 206 as needed and finishes securing the power cables 102 in place. The entire operation is completed efficiently, without the need to remove the circuit breaker from the power distribution assembly 100, thereby reducing downtime and improving the speed and safety of the maintenance procedure.

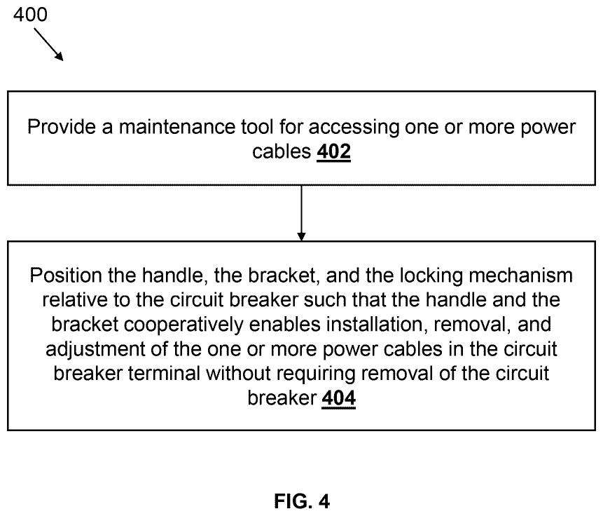

FIG. 4 is a flowchart 400 of a method of accessing power cables in the power distribution assembly using the maintenance tool.

At step 402, a maintenance tool is provided for accessing one or more power cables. The maintenance tool includes a handle configured for single-handed ergonomic operation, with an electrically insulated exterior surface. The tool also includes a bracket mechanically coupled to the handle. The bracket features a specialized cutout designed to support and stabilize the power cables, while reducing mechanical stress on a circuit breaker terminal in the power distribution assembly. Additionally, the maintenance tool incorporates a locking mechanism operable through the handle to engage or disengage the power cables from the circuit breaker terminal.

At step 404, the handle, the bracket, and the locking mechanism are positioned relative to the circuit breaker such that they cooperatively enable the installation, removal, and adjustment of the power cables in the circuit breaker terminal without requiring removal of the circuit breaker. The bracket ensures that the power cables are positioned in a stable orientation, while the locking mechanism, in coordination with the bracket, operates to selectively secure or release the power cables from the circuit breaker terminal, thereby ensuring secure engagement or disengagement of the power cables from the circuit breaker terminal.

Thus, the disclosed maintenance tool and the method overcome the technical limitations of conventional power cable management systems by providing a maintenance tool integrating a single-handed ergonomic handle, an adjustable bracket with a specialized cutout for stabilizing cables, and a locking mechanism that securely engages or disengages the cables from the circuit breaker terminal. This integration allows for efficient cable installation, removal, and adjustment without the need for circuit breaker removal, reducing downtime, enhancing safety, and improving the overall effectiveness of maintenance operations in power distribution assemblies.

The methods, systems, and devices discussed herein are examples. Various embodiments may omit, substitute, or add various procedures or components as appropriate. For instance, in alternative embodiments, the methods may be performed in an order different from that described, and/or various stages may be added, omitted, and/or combined. Also, features described with respect to certain embodiments may be combined in various other embodiments. Different aspects and elements of the embodiments may be combined in a similar manner. The elements herein, are examples and do not limit the scope of the disclosure or claims. Additionally, the techniques discussed herein may provide differing results with different types of context awareness classifiers.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of +20% or +10%, +5%, or +0.1% from the specified value, as such variations are appropriate too in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate too in the context of the systems, devices, circuits, methods, and other implementations described herein.

As used herein, including in the claims, “and” as used in a list of items prefaced by “at least one of” or “one or more of” indicates that any combination of the listed items may be used. For example, a list of “at least one of A, B, and C” includes any of the combinations A or B or C or AB or AC or BC and/or ABC (i.e., A and B and C). Furthermore, to the extent more than one occurrence or use of the items A, B, or C is possible, multiple uses of A, B, and/or C may form part of the contemplated combinations. For example, a list of “at least one of A, B, and C” may also include AA, AAB, AAA, BB, etc.

While illustrative and presently preferred embodiments of the disclosed systems, methods, and/or machine-readable media have been described in detail herein, it is to be understood that the inventive concepts may be otherwise variously embodied and employed, and that the appended claims are intended to be construed to include such variations, except as limited by the prior art. While the principles of the disclosure have been described above in connection with specific apparatuses and methods, it is to be clearly understood that this description is made only by way of example and not as limitation on the scope of the disclosure.

We claim:

1. A maintenance tool for accessing power cables in a power distribution assembly, the maintenance tool comprising:
a handle configured for single-handed ergonomic operation and including an electrically insulated exterior surface;
a bracket mechanically coupled to the handle, the bracket having a specialized cutout configured to support and stabilize one or more power cables while reducing mechanical stress on a circuit breaker terminal of a circuit breaker of the power distribution assembly; and
a locking mechanism integrated within the maintenance tool and operable through the handle to engage or disengage the one or more power cables from the circuit breaker terminal,
wherein the handle, the bracket, and the locking mechanism cooperatively enable installation, removal, and adjustment of the one or more power cables in the circuit breaker terminal without requiring removal of the circuit breaker, and
wherein the bracket positions the one or more power cables in a stable orientation, and the locking mechanism, in coordination with the bracket, operates to selectively secure or release the one or more power cables from the circuit breaker terminal, thereby ensuring secure engagement or disengagement of the one or more power cables from the circuit breaker terminal.

2. The maintenance tool of claim 1, wherein the bracket is adjustably mounted relative to the handle to accommodate circuit breakers of varying dimensions and orientations.

3. The maintenance tool of claim 1, wherein the specialized cutout of the bracket is shaped to receive power cables of multiple diameters and maintain axial alignment during tightening or loosening operations.

4. The maintenance tool of claim 1, wherein the locking mechanism comprises a pressing screw or cam element configured to selectively secure or release the one or more power cables using a single-handed motion applied to the handle.

5. The maintenance tool of claim 1, wherein the locking mechanism further comprises a quick-release element configured to disengage the one or more power cables from the circuit breaker terminal without displacing the bracket or the handle.

6. A method of accessing power cables in a power distribution assembly, the method comprising:
providing a maintenance tool for accessing one or more power cables, wherein the maintenance tool comprises:
a handle configured for single-handed ergonomic operation including an electrically insulated exterior surface,
a bracket mechanically coupled to the handle, the bracket having a specialized cutout configured to support and stabilize the one or more power cables while reducing mechanical stress on a circuit breaker terminal of a circuit breaker in the power distribution assembly, and
a locking mechanism integrated within the maintenance tool and operable through the handle to engage or disengage the one or more power cables from the circuit breaker terminal; and
positioning the handle, the bracket, and the locking mechanism relative to the circuit breaker such that the handle and the bracket cooperatively enable installation, removal, and adjustment of the one or more power cables in the circuit breaker terminal without requiring removal of the circuit breaker,
wherein the bracket positions the one or more power cables in a stable orientation, and the locking mechanism, in coordination with the bracket, operates to selectively secure or release the one or more power cables from the circuit breaker terminal, thereby ensuring secure engagement or disengagement of the one or more power cables from the circuit breaker terminal.

7. The method of claim 6, wherein the bracket is adjustably mounted relative to the handle to accommodate circuit breakers of varying dimensions and orientations.

8. The method of claim 6, wherein the specialized cutout of the bracket is shaped to receive power cables of multiple diameters and maintain axial alignment during tightening or loosening operations.

9. The method of claim 6, wherein the locking mechanism comprises a pressing screw or cam element configured to selectively secure or release the one or more power cables using a single-handed motion applied to the handle.

10. The method of claim 6, wherein the locking mechanism further comprises a quick-release element configured to disengage the one or more power cables from the circuit breaker terminal without displacing the bracket or the handle.
